(19) United States
(12) Patent Application Publication
(10) Pub. No.: US 2026/0223710 A1
(43) Pub. Date: Jul. 30, 2026

(54) ELECTRONIC DEVICE

(71) Applicants: Innolux Corporation, Miaoli County (TW); nD-HI Technologies Lab, Inc., Taipei City (TW)

(72) Inventors: Ho-Ming Tong, Taipei City (TW); Chun-Yu Chien, Miaoli County (TW); Chih-Chao Chuang, Miaoli County (TW); Ching-Yu Chu, Miaoli County (TW); Shu-Hsien Wu, Miaoli County (TW)

(73) Assignees: Innolux Corporation, Miaoli County (TW); nD-HI Technologies Lab, Inc., Taipei City (TW)

(21) Appl. No.: 19/433,098

(22) Filed: Dec. 26, 2025

Related U.S. Application Data
(60) Provisional application No. 63/774,107, filed on Mar. 19, 2025.
(60) Provisional application No. 63/748,977, filed on Jan. 24, 2025.

(30) Foreign Application Priority Data
Sep. 11, 2025 (CN) 202511298548.3

(51) Int. Cl. H10W 70/692; H10W 40/20; H10W 70/60; H10W 70/63; H10W 74/10; H10W 90/00; H10W 90/10; H10B 80/00; H10D 80/30; H10W 74/15

(52) U.S. Cl. CPC H10W 70/692; H10W 40/231; H10W 70/611; H10W 70/635; H10W 74/141; H10W 90/10; H10W 90/724; H10B 80/00; H10D 80/30; H10W 74/15

(57) ABSTRACT

An electronic device includes a core layer, a first circuit structure, a second circuit structure, an electronic unit, and a connecting component. The core layer includes a conductive through via, an embedding portion, and a peripheral heat-dissipating portion surrounding the embedding portion. The conductive through via passes through the core layer and extends to the upper surface and the lower surface. The first circuit structure is disposed on an upper surface of the core layer and is electrically connected to the conductive through via. The second circuit structure is disposed on a lower surface of the core layer and is electrically connected to the conductive through via. The electronic unit is disposed on the first circuit structure and is electrically connected to the first circuit structure. The connecting component is disposed on the second circuit structure and is electrically connected to the second circuit structure.

### CROSS-REFERENCE TO RELATED APPLICATION

This application claims the priority benefit of U.S. Provisional Application No. 63/748,977, filed on January 24, 2025, U.S. Provisional Application No. 63/774,107, filed on March 19, 2025, and China Application No. 202511298548.3, filed on September 11, 2025. The entirety of each of the above-mentioned patent applications is hereby incorporated by reference herein and made a part of this specification.

### BACKGROUND

### Technical Field

The present invention relates to an electronic device, and particularly relates to an electronic device having improved heat dissipation performance.

### Related Art

Package substrates mostly use organic material as the core substrate, but organic material has poor thermal conductivity and a large coefficient of thermal expansion (CTE), which easily leads to large deformation at high temperatures and is unfavorable for the use of large package substrates. Therefore, a package design is proposed that may reduce warpage or help electronic unit heat dissipation.

### BRIEF DESCRIPTION OF THE DRAWINGS

FIG. 1 is a cross-sectional schematic diagram of an electronic device according to an embodiment of the present disclosure.

FIGS. 2A to 2E are cross-sectional schematic diagrams of a manufacturing method of an electronic device according to an embodiment of the present disclosure.

FIG. 3 is a partial cross-sectional schematic diagram of a first circuit structure of an electronic device according to an embodiment of the present disclosure.

FIG. 4A is a cross-sectional schematic diagram of an electronic device according to another embodiment of the present disclosure.

FIG. 4B is a cross-sectional schematic diagram of a partial step of a manufacturing method of the electronic device of FIG. 4A.

FIG. 4C is a three-dimensional schematic diagram of conductive pillars and solder layers according to another embodiment.

### DESCRIPTION OF THE EMBODIMENTS

The disclosure may be understood through referring to the following detailed description in conjunction with the drawings. It should be noted that in order to facilitate the understanding by the reader and for the conciseness of the drawings, multiple drawings in the disclosure only depict a part of an electronic device, and specific elements in the drawings are not drawn according to actual scale. In addition, the number and the size of each element in the drawings are only for illustration and are not intended to limit the scope of the disclosure.

Throughout the specification and the appended claims of the disclosure, certain words are used to refer to specific elements. Persons skilled in the art should understand that electronic device manufacturers may refer to the same elements by different names. The disclosure does not intend to distinguish the elements with the same function but different names.

In the following specification and claims, words such as "containing" and "comprising" are open-ended words, which should be interpreted as "including but not limited to...".

In addition, relative terms such as "below" or "bottom portion" and "above" or "top portion" may be used in the embodiments to describe the relative relationship between an element and another element in the drawings. It should be understood that if a device in the drawings is flipped upside down, elements described as "below" will become elements described as "above".

In some embodiments of the present disclosure, terms regarding bonding and connection such as "on", "connected", "interconnected", etc., unless otherwise defined, may refer to two structures that are directly in contact or may also refer to two structures that are not directly (indirectly) in contact, wherein there is another structure provided between the two structures. Furthermore, the term "coupling" includes the transfer of energy between two structures through means of direct or indirect electrical connection or the transfer of energy between two separate structures by means of mutual induction.

The terms "about", "equal to", "equivalent" or "same", "substantially", or "roughly" are generally interpreted as within 20% of a given value or range, or interpreted as within 10%, 5%, or 0.5% of the given value or range.

In the present disclosure, optical microscopy (OM), scanning electron microscope (SEM), thin film thickness profiler (α-step), ellipsometer, or other suitable methods may be used to measure the area, width, thickness or height of each element, or the distance or spacing between elements.

In the disclosure, the definition of roughness judgment may be observed by the SEM or the transmission electron microscope (TEM), etc. Under magnification where surface undulations with peak-to-valley distance differences of 0.15 micrometers (μm) to 1μm can be observed, the roughness range is determined by taking a unit length (for example, 10μm) sample to compare the undulation conditions. Here, "appropriate magnification" means that at least one surface may have a roughness (Rz) or an average roughness (Ra) of at least 10 peaks and valleys visible under the field of view of such a magnification.

As used herein, the terms "film" and/or "layer" may refer to any continuous or discontinuous structure and material.

Although the terms first, second, third... may be used to describe various constituent elements, the constituent elements are not limited by the terms. The terms are only used to distinguish a single constituent element from other constituent elements in the specification.

Unless otherwise defined, all terms (including technical and scientific terms) used herein have the same meaning as commonly understood by one of ordinary skill in the art to which this disclosure belongs. It is understood that these terms, such as those defined in commonly used dictionaries, should be interpreted as having a meaning consistent with the related art and the background or context of the present disclosure, and should not be interpreted in an idealized or overly formal manner, unless specifically defined herein.

An electronic device of the disclosure may include a power module, a semiconductor device, a semiconductor package device, a display device, an antenna device, a sensing device, a light emitting device, or a splicing device, but is not limited thereto. According to an embodiment of the disclosure, a manufacturing method of the electronic device provided may be applied, for example, to a wafer-level package (WLP) process or a panel-level package (PLP) process and may adopt a chip first process or a chip last/RDL first process, which will be further described in detail below. The electronic device referred to in the disclosure may include a system on chip (SoC), a system in package (SiP), an antenna in package (AiP), co-packaged optics (CPO), or a combination of the above, but not limited thereto.

Reference will now be made in detail to the exemplary embodiments of the disclosure, and examples of the exemplary embodiments are illustrated in the drawings. Wherever possible, the same reference numerals are used in the drawings and the description to refer to the same or similar parts.

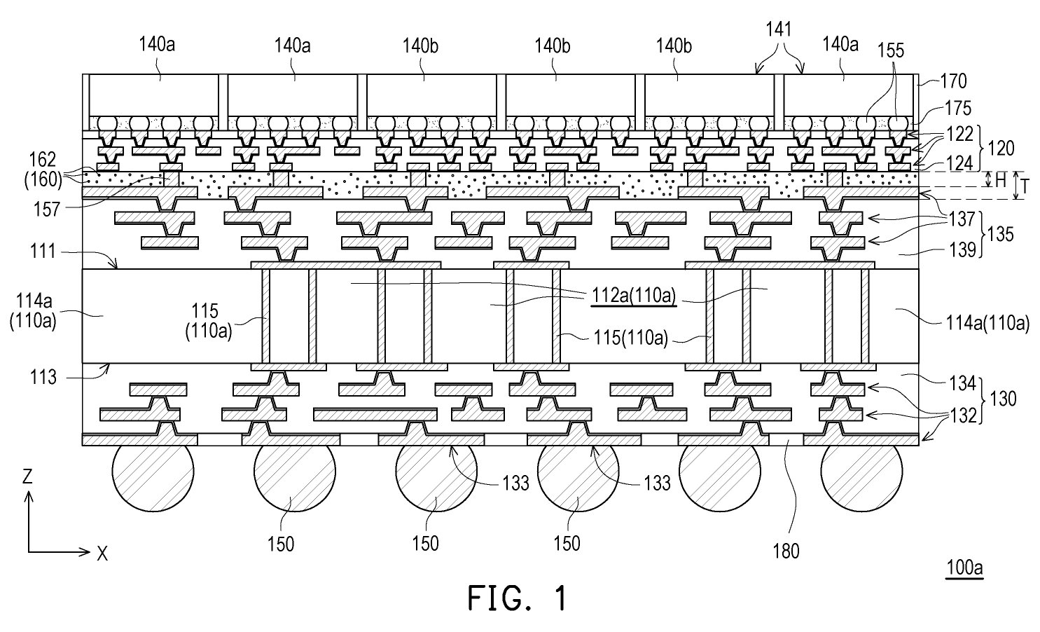

FIG. 1 is a cross-sectional schematic diagram of an electronic device according to an embodiment of the present disclosure. Please refer to FIG. 1, in this embodiment, the electronic device 100a includes a core layer 110a, a first circuit structure 120, a second circuit structure 130, electronic units 140a, 140b, and connecting components 150. The core layer 110a includes conductive through vias 115, an embedding portion 112a, and a peripheral heat dissipation portion 114a surrounding the embedding portion 112a, and has an upper surface 111 and a lower surface 113 opposite to each other. The conductive through vias 115 pass through the core layer 110a and extend to the upper surface 111 and the lower surface 113. The first circuit structure 120 is configured on the upper surface 111 of the core layer 110a and is electrically connected to the conductive through vias 115. The second circuit structure 130 is configured on the lower surface 113 of the core layer 110a and is electrically connected to the conductive through vias 115. The electronic units 140a, 140b are configured on the first circuit structure 120 and are electrically connected to the first circuit structure 120. The connecting components 150 are configured on the second circuit structure 130 and are electrically connected to the second circuit structure 130. The conductive through vias 115 of the core layer 110a may electrically connect the first circuit structure 120 and the second circuit structure 130.

Vias may be formed in the core layer 110a through laser or mechanical drilling, then, a plated metal layer is formed in the vias and on the upper surface 111 and the lower surface 113 of the core layer 110a through electroplating, thereafter, the plated metal layer is patterned to form the conductive through vias 115. The diameter of the vias (i.e., the width in the X-axis direction) is, for example, 10 micrometers to 300 micrometers. The conductive through vias 115 may be hollow conductive through via structures. The conductive through vias 115 may include filler materials, such as epoxy or thermal dissipation materials, such as graphite or silver nanoparticles, but are not limited thereto. The materials of the embedding portion 112a and the peripheral heat dissipation portion 114a of the core layer 110a may be the same. The materials of the embedding portion 112a and the peripheral heat dissipation portion 114a of the core layer 110a may be different, wherein the thermal conductivity of the peripheral heat dissipation portion 114a is greater than the thermal conductivity of the embedding portion 112a. The material of the core layer 110a may be, for example, silicon oxide (SiO), silicon nitride (SiN), aluminum nitride (AlN), silicon carbide (SiC), aluminum silicon carbide (AlSiC), diamond, or combinations of the above materials, wherein the above materials are all inorganic materials, and silicon oxide, silicon nitride, aluminum nitride, silicon carbide, and aluminum silicon carbide may be regarded as ceramic materials. The a coefficient of thermal expansion (CTE) of the core layer 110a is 1*10⁻⁶/K to 15*10⁻⁶/K, and the thermal conductivity (TC) of the core layer 110a is 180 W/m*K to 2000W/m*K. The thickness of the core layer 110a in the Z-axis direction is, for example, 100 micrometers to 1000 micrometers, but is not limited thereto.

The first circuit structure 120 includes a first metal layer 122 and a first dielectric layer 124. The first metal layer 122 may have conductive or signal transmission functions. The material of the first metal layer 122 may be, for example, copper, titanium, nickel, or combinations or alloys of the above materials, but is not limited thereto. The CTE of copper is 16.8*10⁻⁶/K to 17.9*10⁻⁶/K, and the TC of copper is 400 W/m*K to 450W/m*K. The material of the first dielectric layer 124 is, for example, photosensitive polyimide (PSPI), silicon dioxide (SiO₂), or silicon nitride (SiN_{X}), but is not limited thereto. The first circuit structure 120 is, for example, a fine pitch redistribution layer (RDL), and may be electrically connected to electronic units 140a, 140b through connecting components 155 or other bonding components. The material of the connecting components 155 is, for example, copper, nickel, tin, silver, gold, gallium, or combinations thereof, but is not limited thereto.

The second circuit structure 130 may be similar to the first circuit structure 120. The material of the second dielectric layer 134 is, for example, Ajinomoto build-up film (ABF) containing filler, but is not limited thereto. The second circuit structure 130 is, for example, a coarse pitch RDL, and may be electrically connected to external circuits, such as on a circuit board, through connecting components 150 or other bonding components.

A third circuit structure 135 may also be included between the core layer 110a and the first circuit structure 120, wherein the third circuit structure 135 includes a third metal layer 137 and a third dielectric layer 139. The third metal layer 137 may have conductive functions. The material of the third dielectric layer 139 is, for example, PSPI or ABF, but is not limited thereto. The third circuit structure 135 is, for example, a coarse pitch RDL, and may be electrically connected to the first circuit structure 120 through connecting components 157 or other bonding components.

It should be noted that the number of metal layers may be increased or decreased according to requirements. In short, the number of metal layers may be different. The RDL may include at least one dielectric layer and at least one metal layer alternately stacked along direction Z to redistribute circuits and/or enhance circuit fan-out or fan-in area, or different electronic units may be electrically connected to each other through the RDL. The method for forming the RDL may include using dual damascene process, lithography etching process, surface treatment process, laser process, electroplating process, deposition process, combinations of the above processes, or other processes to form at least one dielectric layer and at least one metal layer. The surface treatment process includes roughening or activating the surface of the dielectric layer or metal layer to enhance its adhesion capability. For example, by increasing surface roughness to enhance the bonding force with subsequent film layers.

Please refer to FIG. 1 again. In this embodiment, the electronic device 100a further includes a filler layer 160 disposed between the core layer 110a and the first circuit structure 120, wherein the filler layer 160 covers the connecting components 157 and directly covers the bottom surface of the first circuit structure 120 and the top surface of the third circuit structure 135. That is, the filler layer 160 of this embodiment is located between the third circuit structure 135 and the first circuit structure 120. The connecting components 157 are metal pillars (such as copper studs (Cu stud)), which may be first formed on the third circuit structure 135, and then the filler layer 160 is formed to completely cover the connecting components 157, followed by grinding to expose the connecting components 157, and then the first circuit structure 120 is formed thereon, so that the connecting components 157 electrically connect the first circuit structure 120 and the third circuit structure 135. The height H of the connecting components 157 is 5 micrometers to 100 micrometers. The filler layer 160 is an organic material containing filler 162, and may balance the CTE mismatch between the third circuit structure 135 and the first circuit structure 120 by adjusting its CTE, thickness, and modulus. The size (such as diameter) of the filler 162 is 3 micrometers to 60 micrometers, but is not limited thereto. The thickness T of the filler layer 160 is 15 micrometers to 100 micrometers, but is not limited thereto.

Next, the electronic units 140a, 140b of this embodiment are disposed on the first circuit structure 120 and are electrically connected to the first circuit structure 120 through connecting components 155. The electronic units 140a, 140b may also be electrically connected to the outermost first metal layer 122 of the first circuit structure 120 through hybrid bonding (i.e., direct metal-to-metal bonding). The electronic device 100a of this embodiment may further include an adhesive layer 175 disposed between each electronic unit 140a, 140b and the first circuit structure 120. The adhesive layer 175 may fill the space between the electronic units 140a, 140b and the top surface of the first circuit structure 120 and between two adjacent connecting components 155. In one embodiment, the material of the adhesive layer 175 may include organic or inorganic material. The electronic units 140a, 140b may be, for example, known good die (KGD), passive components, diodes, antenna units, sensors, structures of semiconductor-related processes, or structures of semiconductor-related processes disposed on substrates, but are not limited thereto. Since the periphery of the core layer 110a is the peripheral heat dissipation portion 114a, which has better heat dissipation effect, the electronic unit 140a corresponding to this location may be configured with high-power electronic units, such as power diodes or power transistors, while the electronic unit 140b corresponding to the embedding portion 112a may be configured with low-power electronic units, such as logic integrated circuits (IC) or memory integrated circuits.

Furthermore, in this embodiment, the electronic device 100a may further include an encapsulant 170 disposed on the first circuit structure 120 and encapsulating the electronic units 140a, 140b and the adhesive layer 175, wherein a portion of the encapsulant 170 fills between two adjacent adhesive layers 175 and between two adjacent electronic units 140a, 140b. The encapsulant 170 includes organic or inorganic material.

The connecting components 150 are disposed on the outermost second metal layer 132 of the second circuit structure 130. The electronic device 100a further includes a solder mask 180 covering the peripheral surface of the outermost second metal layer 132 and exposing the bottom surface 133 of the second metal layer 132, wherein the connecting components 150 directly contact the bottom surface 133 of the second metal layer 132. The outermost second metal layer 132 is a Non-Solder Mask Defined (NSMD) pad, but is not limited thereto. Subsequently, the electronic device 100a may be electrically connected to external circuits (such as circuit boards) through the connecting components 150. A heat dissipation cover with heat dissipation fins may be attached to the peripheral surface of the electronic device 100a through Thermal Interface Material (TIM), which may effectively enhance the heat dissipation performance of the overall electronic device.

It should be noted that the following embodiments use the same component reference numerals and partial content as the aforementioned embodiments, wherein the same reference numerals are used to represent the same or similar components, and descriptions of the same technical content are omitted.

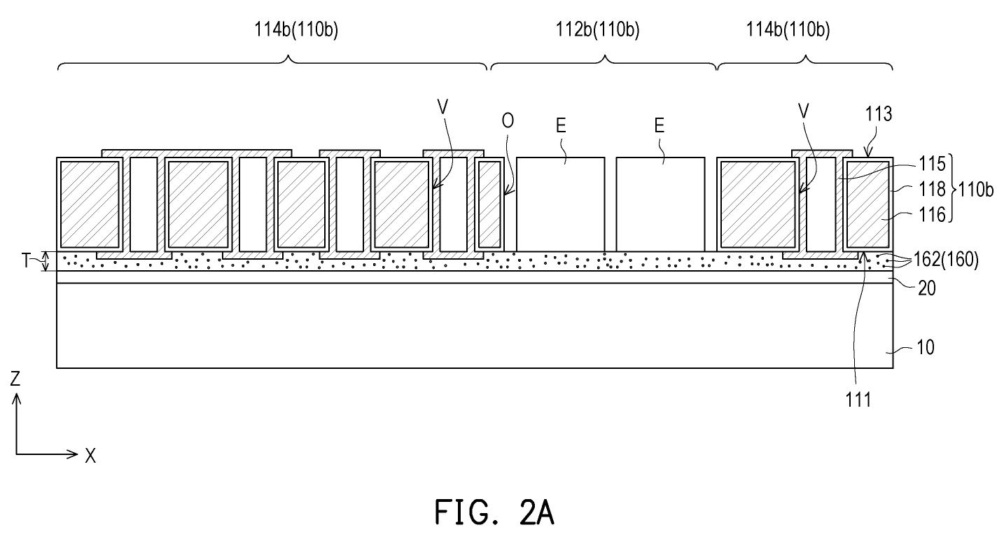

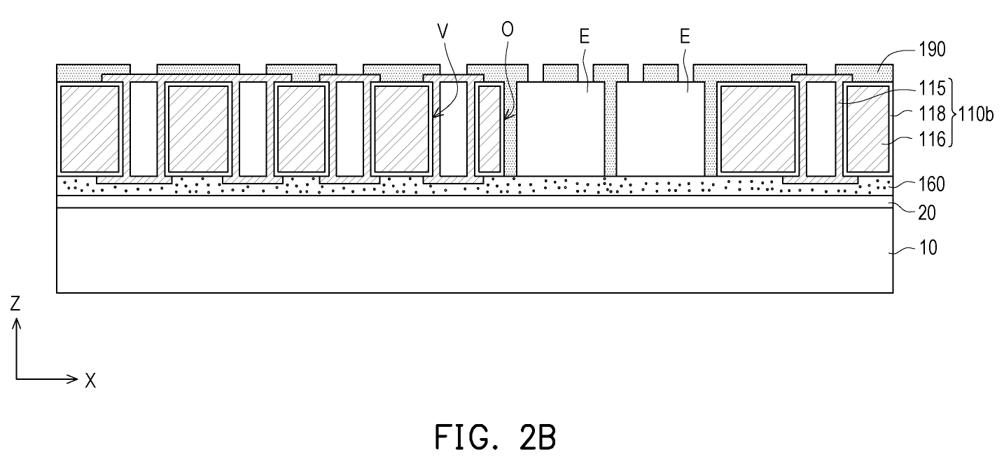

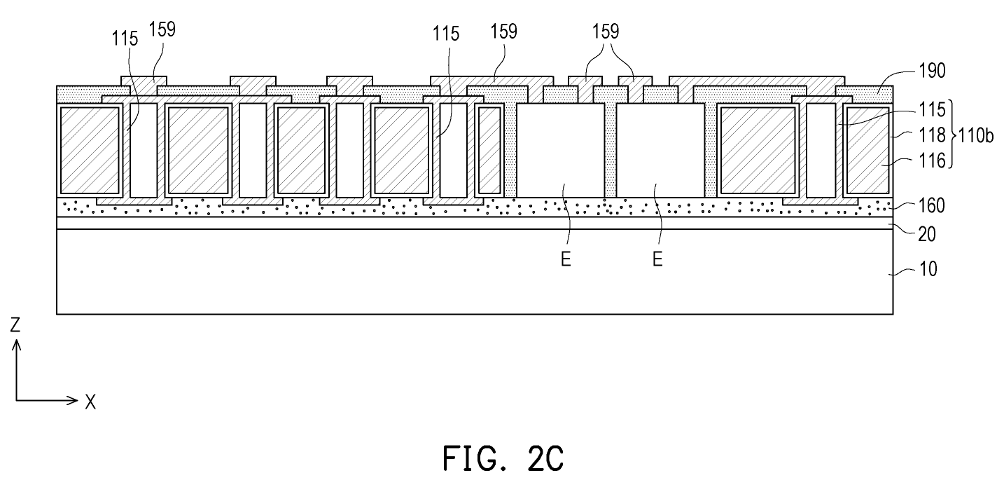

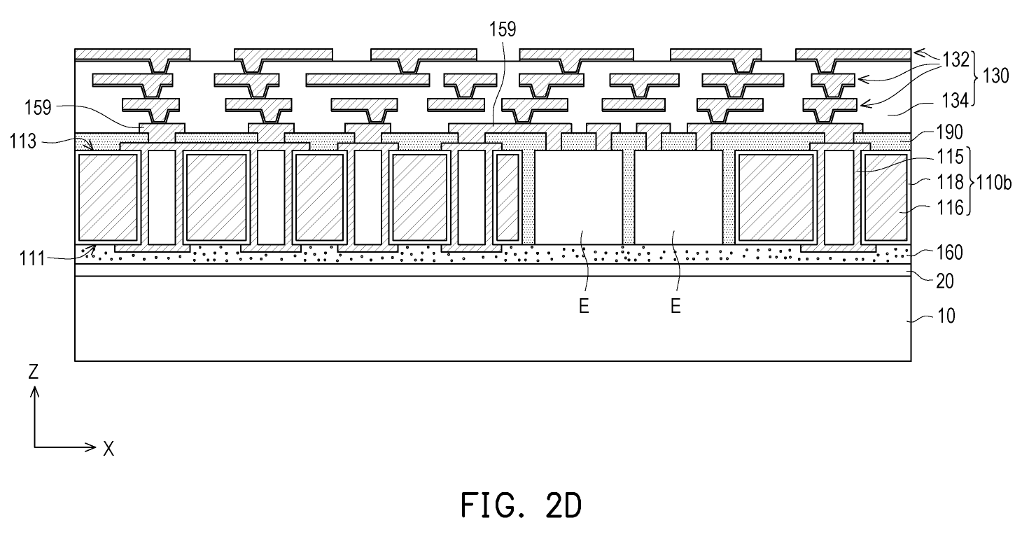

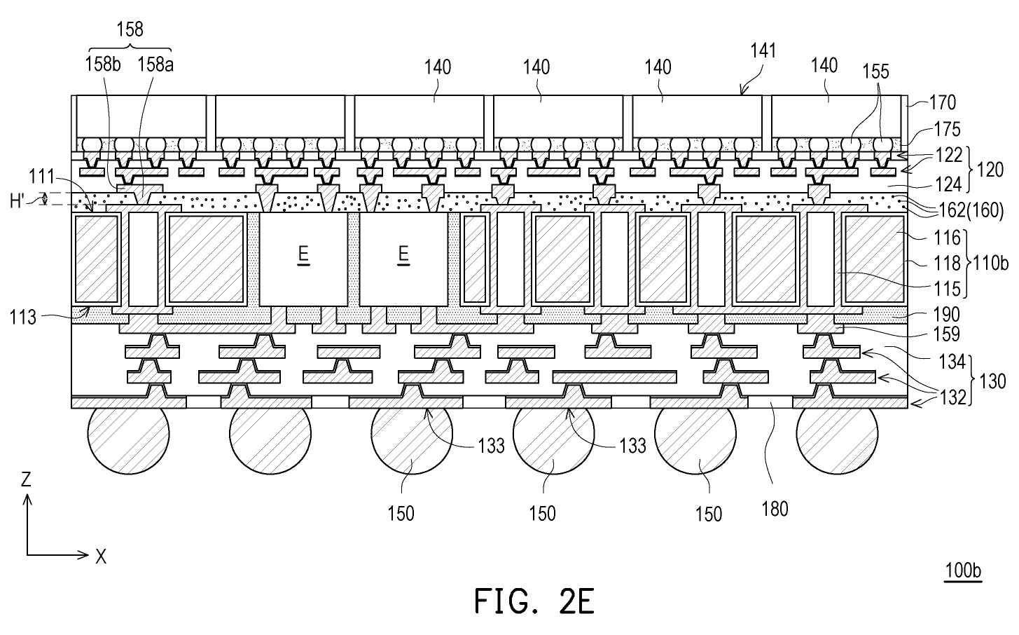

FIGS. 2A to 2E are cross-sectional schematic diagrams of a manufacturing method of an electronic device according to an embodiment of the present disclosure. Please first refer to FIG. 2A, regarding the manufacturing method of the electronic device of this embodiment, first, a temporary substrate 10, a stress adjustment layer 20, a temporary adhesive layer (not shown) and a filler layer 160 are provided, wherein the stress adjustment layer 20 is located between the temporary substrate 10 and the filler layer 160. The temporary substrate 10 is, for example, glass, but is not limited thereto. The stress adjustment layer 20 is a core layer for balancing stress generated by different materials (such as organic material and inorganic material) to forcibly resist warpage.

Next, please refer to FIG. 2A, a substrate is provided. In this embodiment, the substrate is, for example, Invar alloy, which is a conductive substrate. The CTE of Invar alloy is 0.8*10⁻⁶/K, and the TC of Invar alloy is 12W/m*K. The provided substrate or peripheral substrate may also be an insulating substrate, wherein the material of the insulating substrate is, for example, ceramic or diamond, but is not limited thereto. Next, vias and openings penetrating the conductive substrate are formed in the substrate, and an insulating layer is formed on all surfaces of the thermally conductive substrate through, for example, Chemical Vapor Deposition (CVD), thereby forming the conductive portion 116 and the insulation portion 118 encapsulating the conductive portion 116. Subsequently, through electroplating, metal layers are electroplated in the via V and on the upper and lower surfaces of the insulation portion 118, and then, by patterning the metal layers, conductive through vias 115 located in the via V, on part of the upper surface 111, and on part of the lower surface 113 are formed, thereby completing the fabrication of the core layer 110b. Next, the core layer 110b is placed on the temporary substrate 10, wherein the filler layer 160 covers the portion of the conductive through vias 115 located on the upper surface 111. Then, the embedded component E is placed in the opening O that penetrates the core layer 110b and connects the upper surface 111 and the lower surface 113, wherein the embedded component E directly contacts the filler layer 160. The embedded component E may be, for example, a transistor, an integrated circuit, a passive component, or a diode, but is not limited thereto. The position where the embedded component E is located may be the embedding portion 112b of the core layer 110b.

Next, please refer to FIG. 2B, a filler film layer 190 is pressed onto the core layer 110b, and laser drilling is performed on the filler film layer 190 to expose part of the conductive through vias 115 and part of the embedded component E. The filler film layer 190 fills into the opening O and fills the gaps between the embedded components E and between the embedded component E in the opening O. The filler film layer 190 may include organic or inorganic material.

Next, please refer to FIG. 2C, electroplating process and patterning process are performed to form connecting components 159 that connect the conductive through vias 115 and the embedded component E. The connecting components 159 may have conductive function.

Subsequently, a second circuit structure 130 is formed on the lower surface 113 of the core layer 110b, wherein the second circuit structure 130 includes a second metal layer 132 and a second dielectric layer 134, and the second metal layer 132 is electrically connected to the connecting components 159.

Next, please refer to FIGS. 2D and 2E simultaneously, the structure of FIG. 2D is flipped upside down and placed on another temporary substrate with a release film. Subsequently, the temporary substrate 10 and the stress adjustment layer 20 are removed. Next, laser drilling or mechanical drilling is performed on the filler layer 160, and electroplating process and patterning process are performed to form conductive blind vias 158a in the holes and circuits 158b located on the filler layer 160, thereby forming connecting components 158 that electrically connect the conductive through vias 115 and the embedded component E. In other words, the two surfaces of the embedded component E opposite to each other in this embodiment are electrically connected to the first circuit structure 120 and the second circuit structure 130 through the connecting components 158 and the connecting components 159, respectively. The embedded component E may also be electrically connected to at least one of the first circuit structure 120 and the second circuit structure 130. The embedded components E may be electrically connected in series or in parallel with each other. The height H' of the conductive blind vias 158a is, for example, 5 micrometers to 60 micrometers.

Next, please refer to FIG. 2E again, a first circuit structure 120 is formed on the upper surface 111 of the core layer 110b, wherein the first circuit structure 120 is directly formed on the filler layer 160 and is electrically connected to the connecting components 158.

Next, please refer to FIG. 2E again, electronic units 140 are configured on the first circuit structure 120, wherein the electronic units 140 are electrically connected to the first metal layer 122 of the first circuit structure 120 through connecting components 155 or other bonding components. Next, adhesive layers 175 are formed between each electronic unit 140 and the first circuit structure 120. The adhesive layers 175 are used to protect the connecting components 155 or ensure bonding between the electronic units 140 and the first circuit structure 120. Next, an encapsulant 170 is formed on the first circuit structure 120 and covers the electronic units 140 and the adhesive layers 175. Next, a grinding process is performed on the encapsulant 170 to expose the back surfaces 141 of the electronic units 140, which facilitates heat dissipation. Subsequently, the above structure is flipped and placed on yet another temporary substrate with a release film, wherein the back surfaces 141 of the electronic units 140 may directly contact the yet another temporary substrate. Next, a solder mask 180 is formed on the outermost second metal layer 132, wherein the solder mask 180 covers the peripheral surfaces of the outermost second metal layer 132 and exposes the bottom surfaces 133 of the second metal layer 132. Thereafter, connecting components 150 are formed on the second metal layer 132 exposed by the solder mask 180. Finally, the yet another temporary substrate is removed to expose the back surfaces 141 of the electronic units 140, and thus the fabrication of the electronic device 100b is completed through a chip last/RDL first process. The fabrication of the electronic device 100b may also be completed through a chip first process.

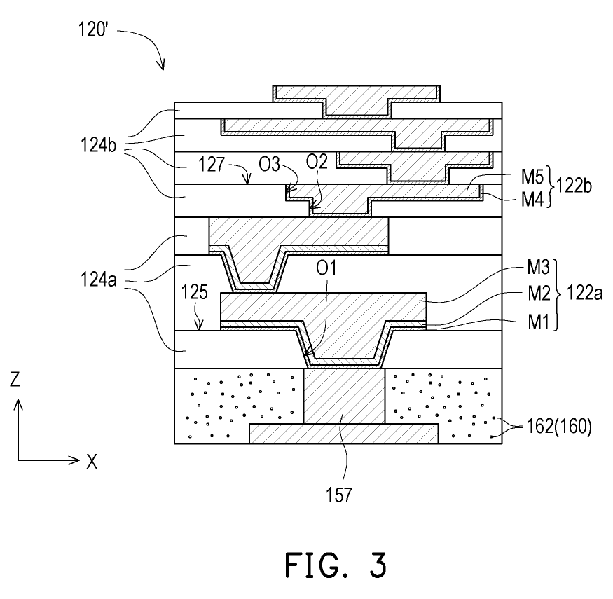

FIG. 3 is a partial cross-sectional schematic diagram of a first circuit structure of an electronic device according to an embodiment of the present disclosure. Please refer to FIG. 1 and FIG. 3 simultaneously, the first circuit structure 120' of this embodiment is similar to the first circuit structure 120 of FIG. 1, and the difference between them is that: in this embodiment, the first circuit structure 120' is embodied as a hybrid structure layer of organic material and inorganic material. In detail, first, a first dielectric layer 124a having an opening O1 is formed on the filler layer 160. Here, the material of the first dielectric layer 124a is, for example, an organic material, such as PSPI. Next, a second metal layer 122a is formed within the opening O1 of the first dielectric layer 124a and extends onto the surface 125 of the first dielectric layer 124a. The second metal layer 122a includes a titanium layer M1, a copper layer M2, and a conductive layer M3, wherein the copper layer M2 is located between the titanium layer M1 and the conductive layer M3. Here, the conductive layer M3 is, for example, copper, but is not limited thereto. The formation method of the first dielectric layer 124a and the second metal layer 122a is similar to the formation method of RDL. Optionally, the above steps are repeated to form multiple layers of the first dielectric layer 124a and multiple layers of the first metal layer 122a.

Next, please refer to FIG. 3 again, a first dielectric layer 124b is formed on the outermost first dielectric layer 124a by a plasma enhanced chemical vapor deposition (PECVD) process. Here, the material of the first dielectric layer 124b is, for example, an inorganic material, such as silicon dioxide (SiO₂) or silicon nitride (SiN_{X}). The material of the first dielectric layer 124b is, for example, an organic material, such as PSPI. Next, a dielectric opening of the first dielectric layer 124b is formed through the aforementioned RDL steps. At this time, the dielectric opening does not penetrate through the first dielectric layer 124b, and the aperture of the dielectric opening is equal to the aperture of the first photoresist opening. Next, a second yellow light lithography process is performed on the photoresist layer to form a dielectric opening O2 on the first dielectric layer 124b and form a second photoresist opening on the photoresist layer. The above steps are repeated to form a dielectric opening O3 communicating with the dielectric opening O2. Here, the dielectric opening O2 and the dielectric opening O3 communicate with each other, and the aperture of the dielectric opening O3 is larger than the aperture of the dielectric opening O2. The dielectric opening O2 is located between the second dielectric opening O3 and the first dielectric layer 124a, and the dielectric opening O2 and the dielectric opening O3 form a stepped structure. The above steps are repeated to form seed material on the surface 127 of the first dielectric layer 124b, on the inner wall of the dielectric opening O2, and on the inner wall of the dielectric opening O3. Next, conductive material is formed on the seed material, wherein the conductive material covers the seed material and fills the dielectric opening O2 and the dielectric opening O3. Thereafter, a polishing process is performed on the conductive material and the seed material to expose the surface 127 of the first dielectric layer 124b, and form a seed layer M4 and a conductive layer M5 located within the dielectric opening O2 and the dielectric opening O3. Here, the conductive layer M5 and the seed layer M4 define a first metal layer 122b. The surface 127 of the first dielectric layer 124b may be flush with the surface of the first metal layer 122b. Next, optionally, the above steps are repeated to form multiple layers of the first dielectric layer 124b and multiple layers of the first metal layer 122b. For example, the first metal layer 122b is formed through a dual damascene fabrication process plus a polishing process, which may have better flatness, wherein the first metal layer 122b has a stepped structure, and the first metal layer 122b has a metal line width and pitch smaller than, for example, 2 micrometers. At this point, the fabrication of the first circuit structure 120' is completed.

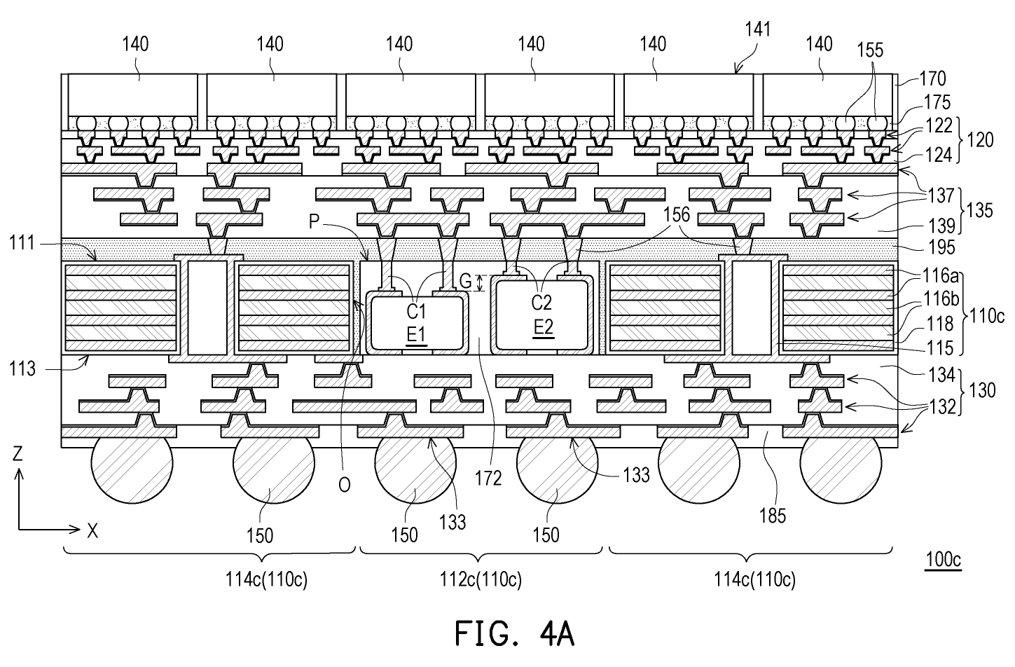

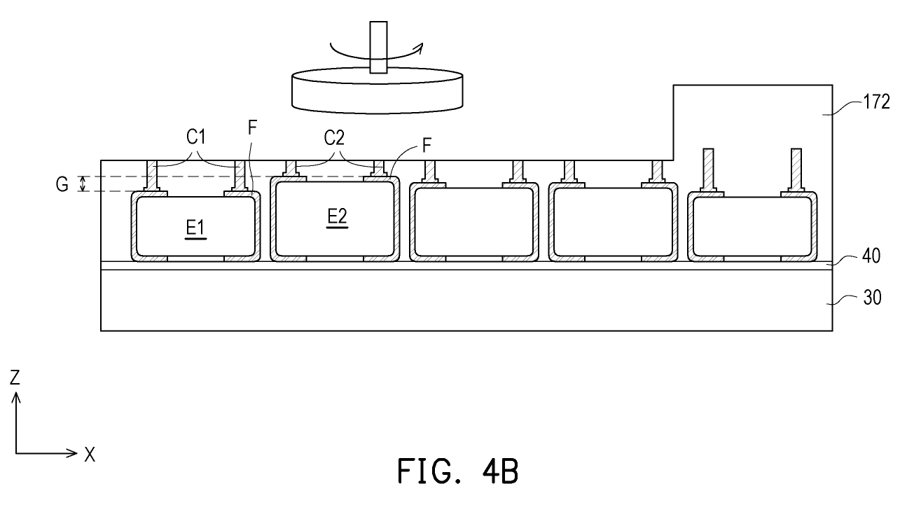

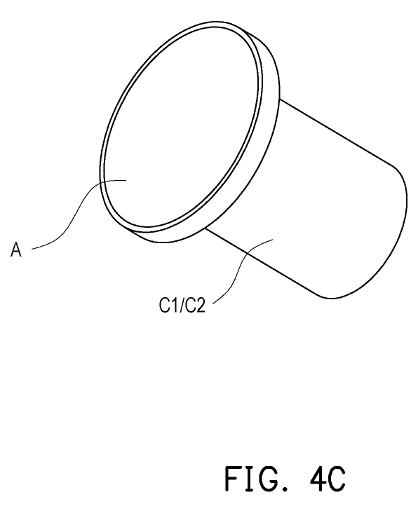

FIG. 4A is a cross-sectional schematic diagram of an electronic device according to another embodiment of the present disclosure. FIG. 4B is a cross-sectional schematic diagram of partial steps of a fabrication method of the electronic device of FIG. 4A. FIG. 4C is a three-dimensional schematic diagram of conductive pillars and solder layers according to another embodiment. Please refer to FIG. 4A, the core layer 110c of this embodiment includes a conductive portion and an insulation portion 118 covering the conductive portion, wherein the conductive portion includes a first portion 116a and a second portion 116b stacked with each other, and the material of the first portion 116a is different from the material of the second portion 116b. The material of the first portion 116a is, for example, metal, such as copper, or ceramic, while the material of the second portion 116b is, for example, Invar alloy. The core layer 110c of this embodiment may adopt an alloy material layer with a small thermal expansion coefficient and combine it with copper metal or any suitable material layer, such as ceramic, to form a sandwich structure, which may effectively improve the thermal deformation of the overall electronic device 100c. Wherein, the number of layers of the first portion 116a and the number of layers of the second portion 116b may be the same or different.

Furthermore, please refer to FIG. 4B, embedded components E1 and E2 are configured on a carrier 30 having a release film 40, such that there is a height difference G between them. The embedded components E1 and E2 are, for example, Surface Mounted Devices (SMD). The height difference G is, for example, 50 micrometers to 150 micrometers. Next, conductive pillars C1 and C2 are respectively formed on conductive terminals F of the embedded components E1 and E2, and are respectively electrically connected to the embedded components E1 and E2. The conductive pillars may be formed on the conductive terminals of the embedded components through a wire bonding process. The number of conductive pillars on each embedded component is determined by the size of each embedded component and the area of the conductive terminals. Next, an encapsulant 172 is formed to completely cover the embedded components E1, E2, conductive pillars C1, and conductive pillars C2. The material of the encapsulant 172 is, for example, an insulating material. Thereafter, portions of the conductive pillars C1 and C2 are removed by grinding, and a singulation cutting process may be selectively performed to form a package P having a flat surface as shown in FIG. 4A.

Next, please refer again to FIG. 4A, the package P is placed within opening O of core layer 110c, and a filler film layer 195 is pressed onto core layer 110c, then laser drilling is performed on the filler film layer 195 to expose portions of conductive through via 115, conductive pillar C1, and conductive pillar C2. The filler film layer 195 may fill into opening O and fill the gap between package P and opening O. The material of encapsulant 172 is the same as the material of filler film layer 195. The material of encapsulant 172 is different from the material of filler film layer 195. Filler, such as polymer, may be selectively filled within encapsulant 172 and filler film layer 195, but is not limited thereto. Subsequently, connecting components 156 are formed within the aforementioned laser drilled holes to electrically connect conductive through via 115, conductive pillar C1, and conductive pillar C2. The material of connecting components 156 may be, for example, copper, nickel, tin, silver, gold, gallium, or combinations thereof, but is not limited thereto.

The embedded components E1 and E2 may first be placed within opening O of core layer 110c, and a filler film layer 195 is pressed onto core layer 110c, then laser drilling is performed on the filler film layer 195 to expose portions of conductive through via 115 and conductive terminals of embedded components E1 and E2. Thereafter, connecting components 156, conductive pillar C1, and conductive pillar C2 that are electrically connected to conductive through via 115 and embedded components E1 and E2 are formed within the laser drilled holes through electroplating. The position where embedded components E1 and E2 are located may be embedding portion 112c of core layer 110c, while the position of the area surrounding embedding portion 112c is peripheral heat dissipation portion 114c.

Please refer to FIGS. 4B and 4C simultaneously. To increase the bonding force between conductive pillars C1 and C2 and embedded components E1 and E2, the electronic device further includes solder layer A, configured between conductive pillars C1 and C2 and embedded components E1 and E2, wherein the material of solder layer A is different from the material of conductive pillars C1 and C2. The material of solder layer A includes tin, nickel, gold, gallium, combinations thereof, or other suitable metals.

A first circuit structure 120 is formed on filler film layer 195 and electrically connected to connecting components 156. In other words, package P of this embodiment is electrically connected to first circuit structure 120 through only one side surface. Connecting components that are electrically connected to second circuit structure 130 may also be formed at the other side surface of package P, thereby forming a structural configuration where first circuit structure 120 and second circuit structure 130 are respectively connected to both sides.

Furthermore, in this embodiment, a third circuit structure 135 may also be included between upper surface 111 of core layer 110c and first circuit structure 120, wherein third circuit structure 135 includes third metal layer 137 and third dielectric layer 139.

Additionally, solder mask 185 of this embodiment covers the surrounding surface of the outermost second metal layer 132 and exposes part of bottom surface 133 of second metal layer 132, while connecting component 150 directly contacts bottom surface 133 of second metal layer 132. The outermost second metal layer 132 is a solder mask defined (SMD) pad, but is not limited thereto.

Finally, it should be noted that the above embodiments are only used to illustrate, but not to limit, the technical solutions of the disclosure. Although the disclosure has been described in detail with reference to the above embodiments, persons skilled in the art should understand that the technical solutions described in the above embodiments may still be modified or some or all of the technical features thereof may be equivalently replaced. However, the modifications or replacements do not cause the essence of the corresponding technical solutions to deviate from the scope of the technical solutions of the embodiments of the disclosure

What is claimed is:

1. An electronic device, comprising:
a core layer, comprising a conductive through via, an embedding portion and a peripheral heat dissipation portion surrounding the embedding portion, and having an upper surface and a lower surface opposite to each other, the conductive through via passing through the core layer and extending to the upper surface and the lower surface;
a first circuit structure, configured on the upper surface of the core layer, and electrically connected to the conductive through via;
a second circuit structure, configured on the lower surface of the core layer, and electrically connected to the conductive through via;
an electronic unit, configured on the first circuit structure, and electrically connected to the first circuit structure; and
connecting components, configured on the second circuit structure, and electrically connected to the second circuit structure.

2. The electronic device as claimed in claim 1, further comprising:
an embedded component, the core layer further comprising an opening penetrating through the core layer and connecting the upper surface and the lower surface, the embedded component being located within the opening, and electrically connected to at least one of the first circuit structure and the second circuit structure.

3. The electronic device as claimed in claim 2, further comprising:
a conductive pillar or laser via, configured on the embedded component, and electrically connecting the embedded component and the first circuit structure.

4. The electronic device as claimed in claim 3, further comprising:
a solder layer, configured between the conductive pillar and the embedded component, wherein a material of the solder layer is different from a material of the conductive pillar.

5. The electronic device as claimed in claim 4, wherein the material of the solder layer comprises tin, nickel, gold, gallium, or a combination of the aforementioned metals.

6. The electronic device as claimed in claim 1, further comprising:
a filler layer, configured between the core layer and the first circuit structure.

7. The electronic device as claimed in claim 6, wherein the filler layer contains filler, a size of the filler being between 3 micrometers and 60 micrometers.

8. The electronic device as claimed in claim 6, wherein a thickness of the filler layer is between 15 micrometers and 100 micrometers.

9. The electronic device as claimed in claim 1, wherein a thermal conductivity of the peripheral heat dissipation portion of the core layer is greater than a thermal conductivity of the embedding portion.

10. The electronic device as claimed in claim 1, wherein the core layer comprises a conductive portion and an insulation portion, the insulation portion covering the conductive portion.

11. The electronic device as claimed in claim 10, wherein the conductive portion comprises a first portion and a second portion stacked with each other, a material of the first portion being different from a material of the second portion.

12. The electronic device as claimed in claim 1, wherein a material of the core layer comprises silicon oxide, silicon nitride, aluminum nitride, silicon carbide, aluminum silicon carbide, diamond, or a combination of the aforementioned materials.

13. The electronic device as claimed in claim 1, wherein a coefficient of thermal expansion of the core layer is 1*10⁻⁶/K to 15*10⁻⁶/K.

14. The electronic device as claimed in claim 1, wherein a thermal conductivity of the core layer is 180 W/m*K to 2000W/m*K.

15. The electronic device as claimed in claim 1, wherein a thickness of the core layer is between 100 micrometers to 1000 micrometers.

16. The electronic device as claimed in claim 1, wherein a material of the peripheral heat dissipation portion of the core layer comprises alloy, ceramic, or diamond.

17. The electronic device as claimed in claim 1, further comprising:
an encapsulant, configured on the first circuit structure and covering the electronic unit, the encapsulant exposing a back surface of the electronic unit.

18. The electronic device as claimed in claim 17, wherein a material of the encapsulant comprises organic material or inorganic material.

19. The electronic device as claimed in claim 1, wherein the first circuit structure is a fine pitch redistribution layer, and the second circuit structure is a coarse pitch redistribution layer.

20. The electronic device as claimed in claim 1, further comprising:
an adhesive layer, filled between the electronic unit and a top surface of the first circuit structure.
